(19) United States
(12) Patent Application Publication
(10) Pub. No.: US 2011/0251805 A1
(43) Pub. Date: Oct. 13, 2011

(54) Sensor Assembly, Tachograph Assembly and Method for Recognition of a Manipulation

(76) Inventor: Horst Plankenhorn, Villingen-Schwenningen (DE)

(21) Appl. No.: 13/139,976

(22) PCT Filed: Nov. 27, 2009
(86) PCT No.: PCT/EP09/65959

§ 371 Date: Jun. 15, 2011

(30) Foreign Application Priority Data
Dec. 15, 2008 (DE) 10-2008-061.924.8

(51) Int. Cl. G06F 19/00; G01R 33/06; G01R 33/02

(52) U.S. Cl. 702/57; 324/244; 324/251

(57) ABSTRACT

A sensor assembly a tachograph assembly and a method for recognition of a manipulation by a magnet having a sensor and a device for signal processing. In order to design the sensor assembly such that a manipulation by a magnet is recognized, the sensor signal is supplied to a second comparator of the device for signal processing that compares the sensor signal to a specified operating range and initiates a manipulation signal if a value of the sensor signal is outside of the operating range.

### PRIORITY CLAIM

This is a U.S. national stage of Application No. PCT/EP2009/065959, filed on Dec. 12, 2009, which claims priority to German Application No: 10 2008 061 924.8, filed: Dec. 15, 2008, the contents of which are incorporated herein by reference.

### BACKGROUND OF THE INVENTION

1. Field of the Invention

The subject matter of the invention is a sensor arrangement, a tachograph arrangement, having such a sensor arrangement and a method for recognizing manipulation on a sensor arrangement.

2. Related Art

In the field of operational data recording for a commercial vehicle, manipulations are frequently attempted on account of the documentary nature of the recordings. In the past, particularly the tachographs themselves were affected by these attempts. Since the introduction of digital tachographs, improved encryption operations mean that manipulation attempts on a tachograph itself are in sharp decline. Increasingly, manipulation attempts are being observed on the sensor arrangements that comprise the pulse generators for the tachographs and on the interfaces of the sensor arrangement to the gearbox. The demands on the sensor arrangements can be found in the international standard ISO 16844-3 “Road vehicles—Tachograph systems—Part 3: Motion sensor interface”, inter alia.

WO 97/35282 A1 discloses a method for avoiding manipulations on the transmission link for a pulse generator signal to a control device, and also an appropriate data transmission apparatus. However, manipulation of the measured variable from the sensor cannot be detected.

A further opportunity for manipulation involves manipulating the pulse generator signals transmitted in real time. One method for avoidance is disclosed in DE 10 2004 043 052 B3.

A further opportunity for manipulation involves the use of a manipulated pulse generator. A method for recognizing the presence of a manipulated pulse generator of this kind is described in DE 195 22 257 A1.

EP 0 892 366 B1 describes a method for avoiding manipulations on a taximeter or a tachograph in which a countermeasure is introduced if a pulse generator signal representing the vehicle speed is amplitude-modulated. This prevents the pulse generator signal from being overlaid with a pulse frequency from a second signal at a different frequency. However, the method is unable to provide a solution if the pulse generator signal is manipulated such that the pulse frequency has a tendency toward zero. Overlaying the second signal would result in the tachograph measuring exclusively the frequency of the second signal.

The above methods are unsuitable for recognizing manipulation of the variable that is to be measured itself. Thus, when using sensors provide a sensor signal dependent on a magnitude of a magnetic field, manipulation can be performed using an additional magnet: the additional magnet is fitted directly to the gearbox or directly to the sensor arrangement. The magnetic field from the additional magnet is overlaid on the sensor magnetic field that is present in the region of the sensor, and modulated on the basis of a gearbox movement, such that the modulation of the sensor magnetic field is small in comparison with the additional magnetic field. This results in displacement of the operating point of the sensor arrangement and results in an erroneous pulse generator signal. This type of manipulation is explained in detail by means of FIGS. 1a-d.

### SUMMARY OF THE INVENTION

It is an object of the present invention to provide a sensor arrangement, a tachograph arrangement, and a method for reliably recognizing an aforementioned manipulation.

The sensor arrangement according to one embodiment of the invention comprises a sensor and an apparatus for signal processing a sensor signal. The sensor signal produced by the sensor exhibits a proportional dependency on the magnitude of a magnetic field and can be transferred both in digital and in analog form to the apparatus for signal processing. A suitable analog sensor signal is a Hall voltage and a suitable digital sensor signal is a pulse-width-modulated signal produced from the Hall voltage.

The sensor signal is transmitted to an input of the apparatus for signal processing. The apparatus is designed such that a first comparator is present that compares the sensor signal with at least one threshold value and takes this as a basis for producing a pulse generator signal having a first or second value, or situated in a first or second value range.

An essential feature of one embodiment of the invention is that the apparatus is designed such that a second comparator is present that compares the sensor signal with a prescribed operating range and initiates a manipulation signal if a value of the sensor signal is outside of the operating range in the manipulation range, for example once, periodically, quasi-periodically, or at least in stages. By way of example, the operating range may be defined over a prescribed range of values for admissible values of the sensor signal.

The operating range is set such that all values of the sensor signal occur in the nominal operating state of the sensor arrangement are covered. In this context, allowance is advantageously made for the components used in the sensor arrangement to be able to have a drift or manufacturing tolerances. It is also possible to take account of changes which occur in the course of aging processes. The operating range is stored in the second comparator.

The at least one threshold value is defined such that within a pulse cycle one value of the sensor signal in the nominal operating state is above the threshold value and a further value of the sensor signal in the nominal operating state is below the threshold value.

If the sensor arrangement is operated properly in the actual operating state, i.e. during everyday operations, the values of the sensor signal do not reach values outside of the operating range: the sensor signal moves periodically or quasi-periodically between a maximum value and a minimum value.

If an additional magnetic field is overlaid on the sensor magnetic field and brought into the region of the sensor arrangement in the actual operating state, the sensor signal shifts by an amount proportional to the influence of the external magnetic field. The operating range has been chosen such that at least one value of the sensor signal is outside the defined or prescribed operating range and a manipulation signal is initiated if the offset in the sensor signal is of such magnitude that the state of the pulse generator signal would no longer change. The manipulation signal may comprise an (abrupt) change in a signal, the absence of a signal or the generation of a signal and is output at an output of the apparatus for signal processing. By way of example, the manipulation signal can be processed further in further apparatuses of the sensor arrangement or of a tachograph arrangement.

In the case of a tachograph arrangement, the manipulation signal can use an apparatus, associated with a tachograph, for producing an error function and/or an error log in order to trigger a malfunction in the tachograph, to disable the tachograph or to initiate the creation of an error log. By way of example, the error log can be transmitted to an external data processing installation during maintenance or updating of the tachograph.

The sensor arrangement is thus protected by virtue of manipulation not necessarily being prevented but rather resulting in the output of a manipulation signal. The manipulation signal can disable a connected tachograph (or else a taximeter) and trigger a malfunction which can be rectified only in a specialist workshop.

It is also advantageous that the magnetic field can be measured by popular sensors. It is merely necessary for the second comparator to be arranged, Whether the apparatus is designed for signal processing as a printed circuit board with components arranged thereon, as logic circuitry for a microcontroller, in the form of a piece of software or firmware situated on a microcontroller, or hybrid forms of the preceding examples is dependent on the intended use of the sensor arrangement.

In one embodiment, the first comparator processes at least two threshold values. The two threshold values may define a switching hysteresis function, i.e. a first threshold value is smaller than a second threshold value and the state of the pulse generator signal is changed only if one value of the sensor signal is below the first threshold value and a further value of the sensor signal exceeds the second threshold value. The switching hysteresis function makes the apparatus more robust toward fluctuations in the sensor signal.

It has also been found to be particularly advantageous if the switching hysteresis function is a dynamic (or matchable or readjustable) switching hysteresis function. In the event of a manipulation, the threshold values are matched to the offset in a sensor signal which occurs on account on the magnet in relation to threshold values that are readjusted on the basis of the manipulation, so that the pulse generator signal continues to map the profile of the sensor signal. Often, the dynamic readjusting is limited in its range of action. It should also be noted that the dynamic readjusting is also possible with just one threshold value. In addition, the dynamic readjusting of the threshold values has the advantage that the sensor also operates statically.

In one embodiment, the sensor signal is readjusted dynamically. In this case, the sensor signal is relieved of its low-frequency component, so that manipulation using a static magnetic field is largely prevented. The readjusting of the sensor signal has the advantage that it is not possible for a plurality of variables from the sensor arrangement to be influenced by tolerances or different drifts.

In one embodiment, the apparatus has a third comparator, wherein the latter compares the sensor signal with a safe operating range and the safe operating range is covered completely by the operating range. By way of example, the safe operating range may be defined by a range of values which is situated in the operating range.

In this case, the safe operating range can be chosen in accordance with the operating range such that all values of the sensor signal which are ascertained in the nominal operating state are likewise covered.

A guard band is created between the operating range and the safe operating range. If a value of the sensor signal is within the guard band, an evaluation unit can initiate a comparison with the pulse generator signal: if the pulse generator signal does not alter for a particular period of time, a malfunction or a maintenance requirement for a tachograph connected to the sensor arrangement is indicated.

In combination with dynamic readjusting, the guard band (or the operating range or the safe operating range) can be chosen such that dynamic readjusting of the threshold values is possible in accordance with the magnitude of the guard band: on account of the dynamic readjusting of the threshold values, the pulse generator signal continues to map the profile of the sensor signal; however, it is simultaneously found that an alleged manipulation is taking place, since values of the sensor signal are situated in the guard band. If the manipulating magnetic field is amplified, so that dynamic readjusting is no longer possible, the sensor signal migrates at least in stages into the manipulation range and thus prompts the initiation of a manipulation signal.

Further embodiments can be found in the further subordinate claims and in the exemplary embodiments.

### BRIEF DESCRIPTION OF DRAWINGS

The method according to the invention, the sensor arrangement and the tachograph arrangement will be explained in more detail with reference to exemplary embodiments, as illustrated in the figures, in which

FIGS. 1a-d are a method and arrangements based on the prior art;

FIG. 2 is a method based on the prior art;

FIGS. 3a and b are an exemplary embodiment of the method according to the invention and a sensor arrangement;

FIGS. 4a-c are schematic illustrations of the nominal operating state and of the actual operating state; and

FIG. 5 is an exemplary embodiment of a tachograph arrangement.

### DETAILED DESCRIPTION OF THE PREFERRED EMBODIMENTS

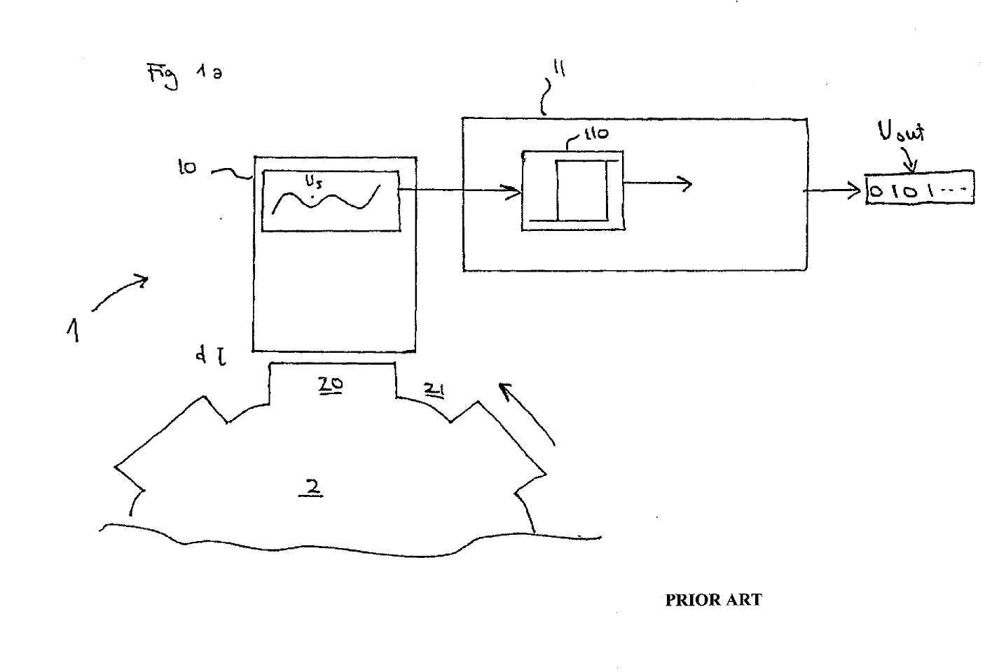

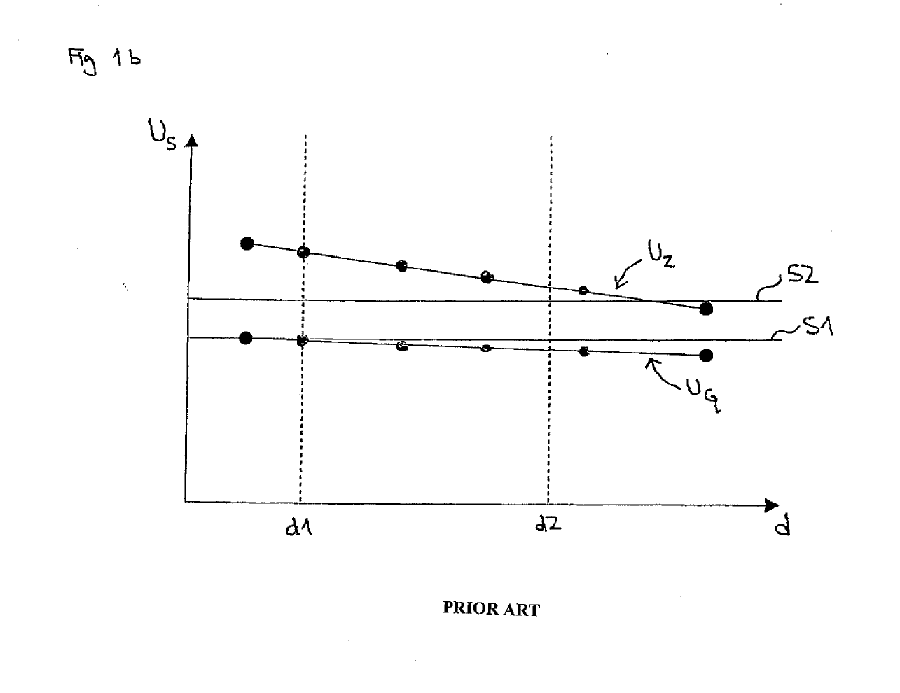

FIGS. 1a-d will first of all be used to explain the problems underlying the invention. FIG. 1a shows a sensor arrangement 1 which has a sensor 10 and an apparatus for signal processing 11. The sensor 10 shown is a Hall sensor having an integrated amplifier, wherein the sensor signal U_{S} is an analog output signal. The sensor 10 is arranged close to a gearwheel 2, wherein the gearwheel 2 rotates in a direction of rotation R when a vehicle is moving and the distance covered by the vehicle is proportional to the speed of the gearwheel or to a variable which is proportional to the speed.

The gearwheel 2 has teeth 20 and gaps 21 situated between the teeth. The interval between the gaps 20 and the sensor 10 is d. When gearwheel 2 is moving in the direction of rotation R, the interval between the gearwheel 2 and the sensor 10 alters on the basis of whether a tooth 20 or a gap 21 is passing the sensor 10. Since the gearwheel is magnetic or a surface of the tooth 20 or of the gap 21 which is facing the sensor 10 has magnetic properties, the sensor 10 registers a modulation in the magnetic field and modulates the sensor signal U_{S} accordingly. The gearwheel is merely one example to illustrate the modulation of the magnetic field.

Since the sensor 10 is a Hall sensor which is operated at a constant Hall current, the Hall voltage is the sensor signal U_{S}.

The sensor signal U_{S} is processed further in an apparatus for signal processing. In the prior art, this apparatus usually has a comparator 110 which keeps at least one threshold value. In this case, the threshold value is chosen such that a value of the sensor signal which is prompted by a tooth 20 is above the threshold value and a value of the sensor signal which is prompted by the gap 21 is below the threshold value. In order to become more robust toward variations and fluctuations in the sensor signal, it is also possible to introduce a switching hysteresis function having two threshold values, as implemented in a Schmitt trigger. The output of the comparator 110 outputs a pulse generator signal Uₒᵤₜ, which is in digital form, for example. In this case, the state “0” may depict the presence of a gap, and the state “1” may depict the presence of a tooth. From the alternating sequence of the pulse generator signal and the associated time intervals, it is possible for a tachograph connected downstream of the sensor arrangement 1 to ascertain the speed of or the distance covered by the vehicle.

FIG. 1b shows a schematic graph which is associated with FIG. 1. The abscissa plots the interval d between tooth 20 and sensor 10. The ordinate plots the value of the sensor signal U_{S} in volts. Between the intervals d1 and d2 there are the possible operating intervals between the sensor 10 and the tooth 20, as shown in FIG. 1a. Smaller intervals than d1 and larger intervals than d2 are possible on account of manufacturing tolerances, wear or manipulations of the interval.

FIG. 1b shows plotted threshold values S1 and S2, which are the threshold values of a Schmitt trigger or of another threshold value detector. The maximum value of the sensor signal U_{S}, as measured by the sensor 10 on the basis of a passing tooth 20, is plotted for different intervals d and is denoted as tooth voltage U_{Z}. The minimum value of the sensor signal U_{S}, as measured on the basis of a passing gap 21, is likewise plotted for different intervals d and is denoted as gap voltage U_{G}. The range of the possible operating intervals, which, in the nominal operating state, are between the intervals d1 and d2, contains all values of the tooth voltage U_{Z} above the second threshold value S2. Similarly, all values of the gap voltage U_{G} are below the threshold value S1. The sensor signal U_{S} thus alternates between a value for the gap voltage U_{G} and a value for the tooth voltage U_{Z}. As a result, the comparator 110 produces an alternating pulse generator signal.

FIG. 1c will be used to explain how a manipulation attempt changes the pulse generator signal such that it merely outputs a single value or state. The upper section A of FIG. 1c shows the sensor 10 with a tooth 20 arranged at the interval d1. Section B shows plots for the sensor signal U_{S} and also the first and second threshold values S1, S2. The third section C shows the time-dependent pulse generator signal Uₒᵤₜ.

When the tooth 20 is passing, the sensor signal U_{S} rises above the threshold value S2 up to that value of the tooth voltage U_{Z} which corresponds to the interval d1. When the tooth has passed, the sensor signal U_{S} drops to an appropriate value for the gap voltage U_{G}. To correspond to the rise above the threshold value S2 and the drop below the threshold value S1, the pulse generator signal Uₒᵤₜ is put into a first state Uₒᵤₜ₁ corresponding to a gap and into a second state Uₒᵤₜ₂ corresponding to a tooth.

At the time tₘ, a magnet M is fitted to the sensor 10, said magnet having a static magnetic field B₀. The magnet M or the additional magnetic field B₀ caused thereby prompts an abrupt rise in the sensor signal U_{S} at the time tₘ. Although the tooth and the gap continue to pass the sensor 10 alternately, the value of the manipulated gap voltage U_{G}′ for the sensor signal U_{S} no longer drops below the threshold value S1. Accordingly, the pulse generator signal Uₒᵤₜ is also no longer reset to the state Uₒᵤₜ₁, but rather remains constantly in the second state Uₒᵤₜ₂. This circumstance is again recorded schematically in FIG. 1d.

FIG. 1d shows plots for the tooth voltage U_{Z}′ and gap voltage U_{G}′ manipulated on account of the static magnetic field B₀ in addition to FIG. 1b. The absolute value of the difference between the values U_{Z}′ and U_{Z} is directly proportional to the strength of the static magnetic field B₀ in this case. In a similar manner to FIG. 1c, it is possible to see that the gap voltage U_{G}′ no longer drops below the threshold value S1. Since the tachograph ascertains the covered distance on the basis of the alternating pulse generator signals, the distance can no longer be transmitted to the tachograph.

FIG. 2 shows a solution from the prior art in order to prevent a manipulation attempt, as explained with reference to FIGS. 1c and 1d. To this end, the threshold values are dynamically readjusted by the apparatus for signal processing. This results in the threshold values S1 and S2 being matched to the manipulated tooth voltages U_{Z}′ and U_{G}′ for the readjusted threshold values S1′ and S2′. A drawback of such a solution is that the dynamic readjusting of the threshold values is limited. This means particularly that the threshold values cannot be readjusted further in the case of very strong magnetic fields, and the manipulation attempt, as set out in FIGS. 1c and 1d, is nevertheless successful.

There now follows an explanation of the solution according to one embodiment of the invention for the successful recognition of a manipulation attempt. FIG. 3a is used to explain the definition of the operating range starting from the nominal operating state of the sensor arrangement, i.e. there is no magnet or a similar instrument of manipulation in the region of the sensor arrangement.

First of all, an operating range for the sensor signal from the sensor arrangement is stipulated. The operating range is defined in addition to the possible intervals between gearwheel and sensor, including the values of the tooth voltage U_{Z} and of the gap voltage U_{G} which occur in nominal operation. When the values of the tooth voltage and of the gap voltage which are relevant to the nominal operating state have been ascertained, an operating range AB is defined which comprises all values of the gap and tooth voltages in the region of the possible intervals. The definition of the operating range AB also takes account of the fact that the interval between the sensor and the gearwheel or a similar apparatus can easily change on the basis of use or is subject to manufacturing tolerances. Furthermore, allowance is made for the fact that the electronics are subject to tolerances and fluctuations in certain ranges.

Outside of the operating range AB there is the manipulation range MB, which comprises values of the sensor signal U_{S} for which it is highly probable that a manipulation attempt can be assumed. Optionally, a safe operating range SAB can additionally be defined which is completely covered by the operating range AB, so that there is a guard band SB at the edges of the safe operating range SAB which is not entered by the gap voltage U_{G} and the tooth voltage U_{Z} in the nominal operating state.

Furthermore, two threshold values S1 and S2 are defined which are connected up to form a switching hysteresis function.

FIG. 3b shows a sensor arrangement 1′ which is used to implement such an operating range AB. The sensor arrangement 1′ has a sensor 10 which is a Hall sensor having an amplifier and which outputs an analog sensor signal. The analog sensor signal is supplied to an apparatus for signal processing 11′, wherein the sensor signal U_{S} passes through a bandpass filter 111 and a first comparator 110′, for example a Schmitt trigger. The output of the first comparator 110 is the pulse generator signal Uₒᵤₜ.

The bandpass filter 111 is used to dynamize the incoming sensor signal U_{S}, i.e. a constant offset—prompted by a magnet which produces a static magnetic field—in the sensor signal is removed from the sensor signal, so that the sensor signal which has been relieved of the offset operates in the range of the at least one threshold value again. The sensor signal which has been relieved of the offset is then supplied to the first comparator for the purpose of generating the pulse generator signal. The lower cutoff frequency chosen for the bandpass filter may be 1 Hz, for example, since in this way only the low-frequency component below the cutoff frequency is removed, but the sensor signal otherwise remains unaffected. There is thus no shift in the threshold values, but rather the sensor signal is shifted into the range of the threshold values. The dynamic readjusting of the sensor signal is disadvantageous in comparison with the dynamic matching of the threshold values in so far as the removal of the low-frequency sensor signal component means that it is no longer possible to establish whether a tooth or a gap is situated in front of the sensor when the gearwheel is stationary, i.e. the sensor no longer operates statically.

Although the equivalent circuit diagram shown in the present case suggests dynamic matching of the sensor signal, a microcontroller can likewise be used to readjust the threshold values dynamically. When the threshold values are readjusted dynamically, the sensor can also operate statically, which also entails advantages for other applications. In particular, both types of readjusting can be combined with the further features of the invention.

The sensor signal U_{S} is also supplied to a second comparator 120, which is in the form of a window discriminator. The window discriminator stipulates the operating range AB. If the sensor signal U_{S} has a value which is situated outside of the operating range AB, the window discriminator outputs a manipulation signal MS. It goes without saying that it is also possible to output a signal in cases in which the sensor signal U_{S} is within the operating range and to dispense with said signal if the sensor signal U_{S} is outside of the operating range.

For the purpose of defining the safe operating range SAB, a further comparator is added, with the sensor signal U_{S} now passing both through the second and through the third comparator.

Although the sensor arrangement 1′ shown in FIG. 3b is shown in the form of a circuit diagram, it is naturally possible for the apparatus 11 for signal processing to be designed as a microcontroller and for the latter to be used to implement functions which perform the task of a first and a second, possibly a third, comparator. For the method according to the invention for recognizing a manipulation, it is important that the sensor signal is examined prior to production of the pulse generator signal to determine whether it is within or outside of the operating range. Unlike in the sensor arrangement 1′ shown in FIG. 3b, it is thus also possible for the sensor signal to be supplied first of all to the second comparator 120 and for the sensor signals to be supplied to the first comparator 110′ only if the sensor signal is within the operating range AB.

The width of the guard band SB can be determined by making the magnitude of the guard band SB dependent on dynamic matching of the threshold values. This means that the width of the guard band substantially corresponds to the dynamically readjustable absolute value of the threshold values or to a smaller absolute value. This means that it is possible to have the manipulation range start precisely when it is no longer possible to dynamically match the threshold values using the first comparator.

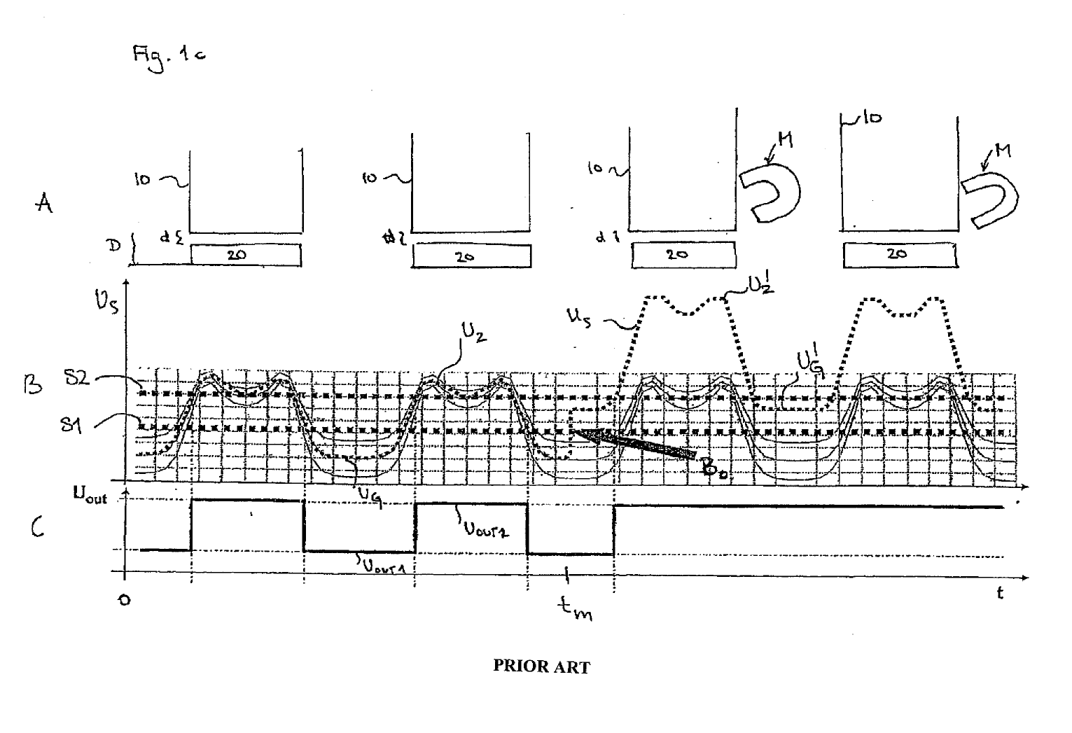

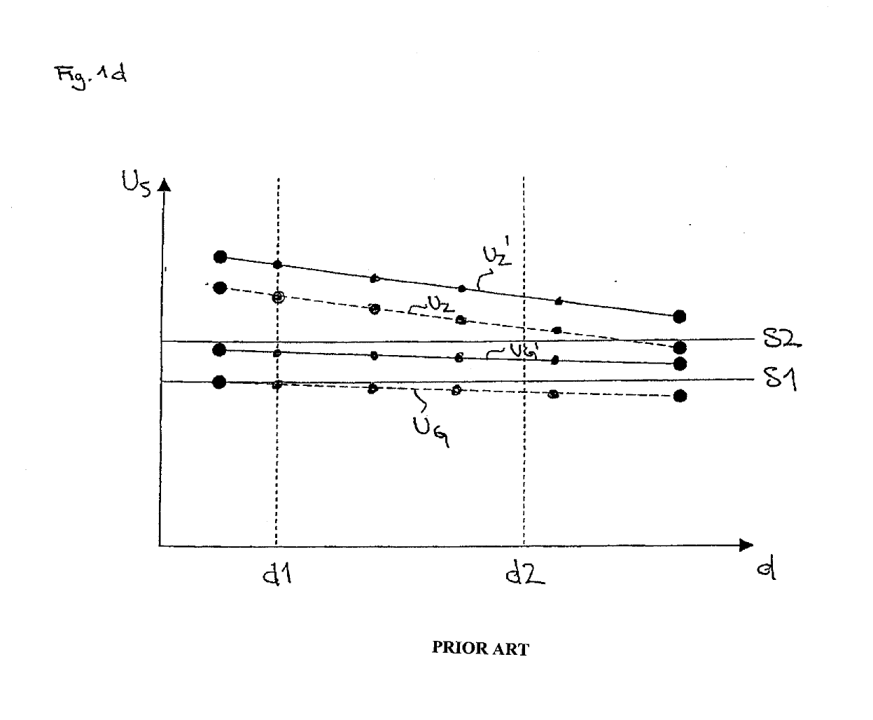

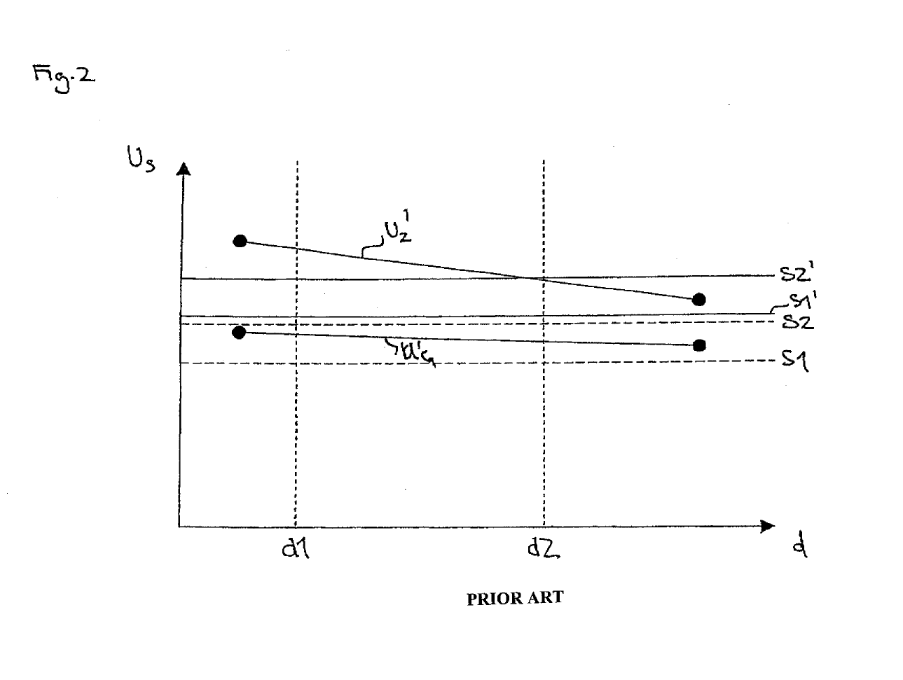

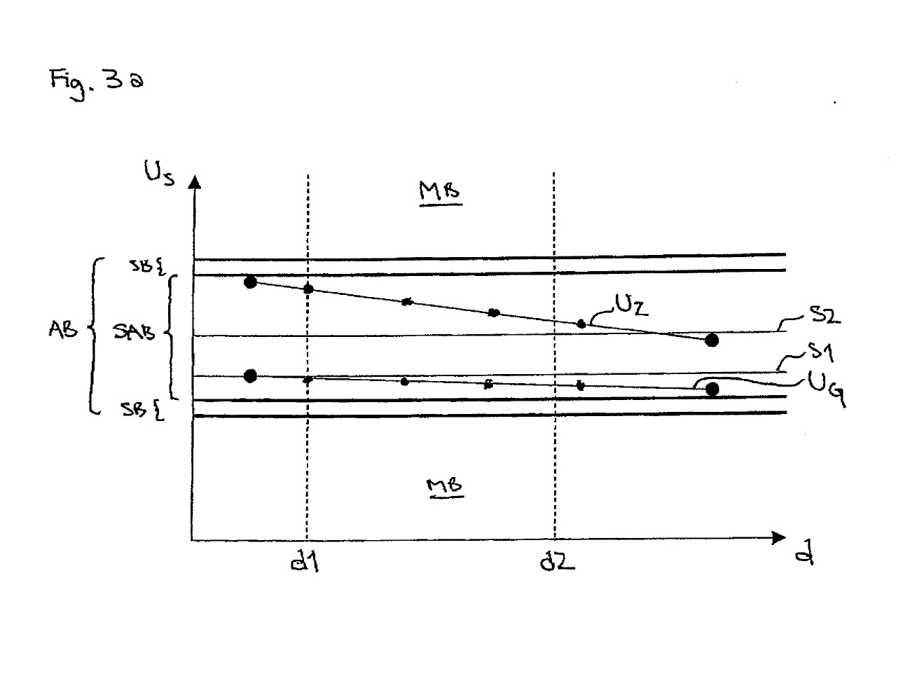

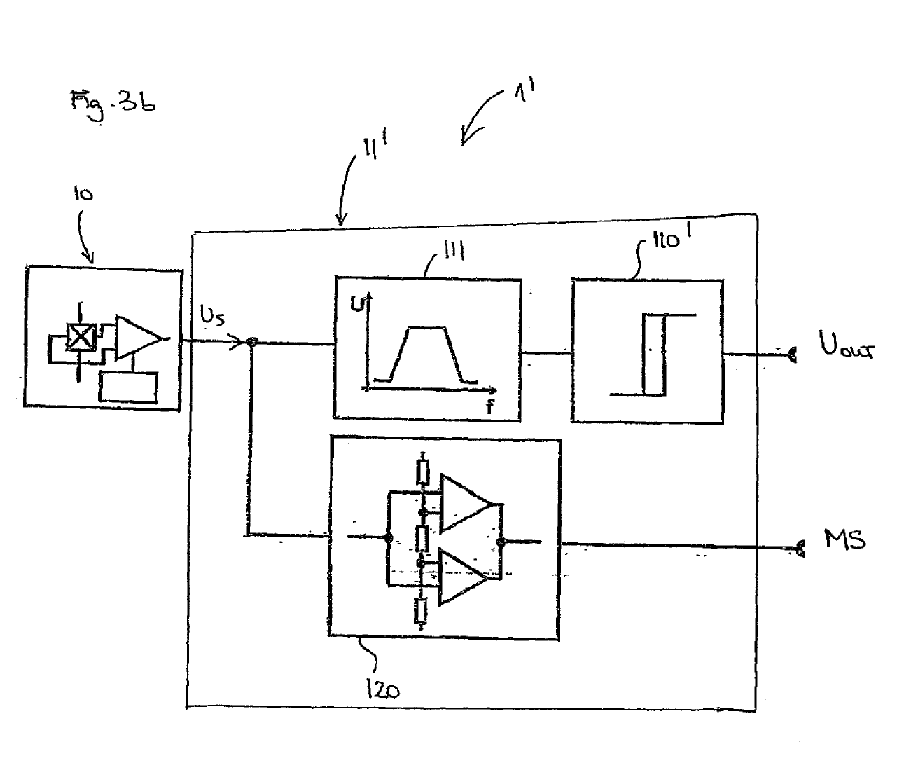

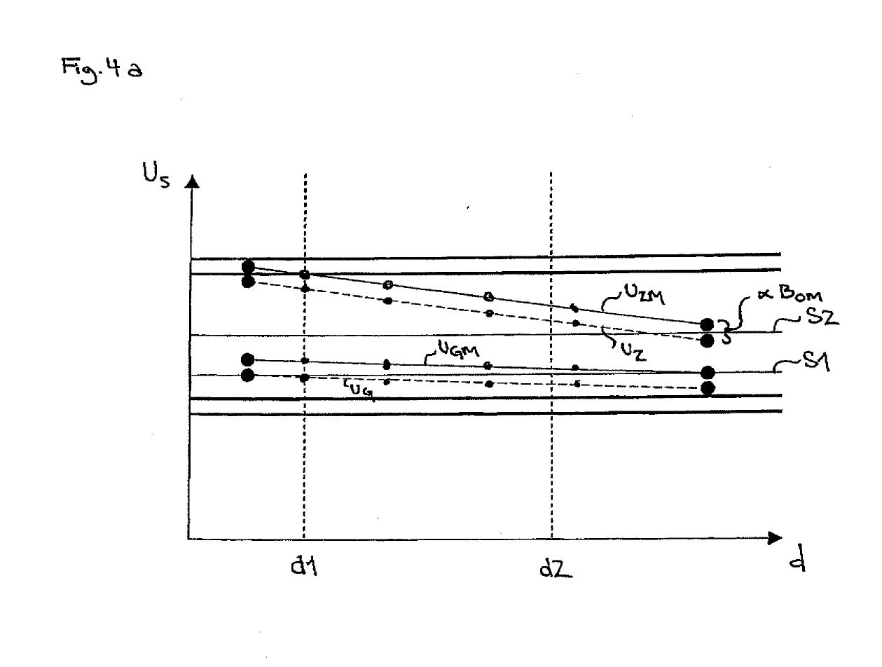

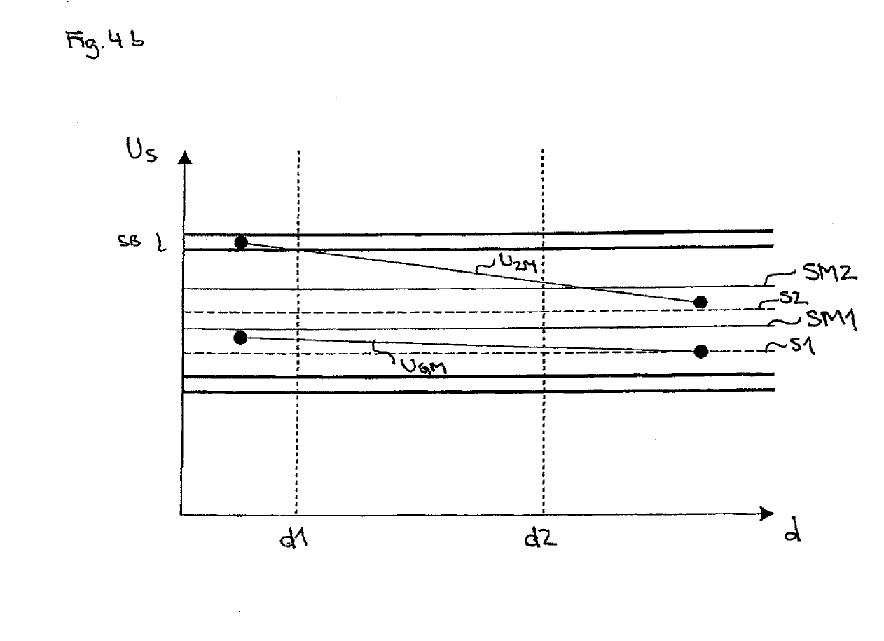

FIG. 4 is used to explain the manner of operation of the sensor arrangement using a few actual operating states, i.e. operating states in which the manipulation is attempted using a magnet in the present case.

In FIG. 4a, the tooth voltage U_{Z} or gap voltage U_{G} has been shifted on the basis of a static magnetic field B_{OM} to produce the manipulated tooth voltage U_{ZM} or the manipulated gap voltage U_{GM}. As can be seen from FIG. 4a, the magnetic field B_{OM} prompts an offset in the gap voltage U_{GM} such that all values of the manipulated gap voltage U_{GM} are above the threshold value S1. At the same time, the tooth voltage U_{ZM} is shifted such that at least for intervals smaller than the interval d1 the tooth voltage U_{ZM} is within the guard band SB.

In the actual operating state illustrated by FIG. 4a, no dynamic matching of the threshold values is performed. This results in no change in the pulse generator signal Uₒᵤₜ taking place, since all values of the gap voltage U_{GM} are above the threshold value S1. Since the chosen operating interval is d1, however, the apparatus for signal processing recognizes that there must be a certain disturbing factor present. Although there is still no manipulation signal initiated, since the values of the tooth voltage U_{ZM1} are within the operating range, a safety signal is initiated which initiates logging of the profile of the pulse generator signal in comparison with the safety signal. It is thus possible to output a request for maintenance of the tachograph when a safety signal is present for a relatively long time and there is simultaneously no change in the pulse generator signal, for example. It is also possible, for example after repeated warnings that a safety signal is present, for a malfunction in the tachograph to be initiated which can be rectified only by a specialist operation.

FIG. 4b shows essentially the same situation as FIG. 4a; with dynamic matching of the threshold values performed from the threshold values S1, S2 to the matched threshold values SM1 and SM2. Although a safety signal continues to be triggered, the values of the pulse generator signal Uₒᵤₜ now alternate, since the gap voltage U_{GM} manipulated on the basis of the static magnetic field B_{OM} are again all below the matched threshold value SM1. Further logging of the profile of the pulse generator signal with the safety signal is initially not necessary; however, it is possible to arrange for the tachograph or the sensor arrangement to undergo maintenance.

FIG. 4c shows an actual operating state in which the sensor arrangement is exposed to the influence of a strong magnetic field B_{ON}. In this case, the tooth voltage U_{Z} and the gap voltage U_{G} are offset by an amount and are shifted to produce the manipulated tooth voltage U_{ZN} and gap voltage U_{GN}. The amount of the offset between the nominal operating state and the actual operating state is of such magnitude that it is no longer possible to perform dynamic matching of the threshold values S1 and S2. As can be seen, however, the value of the tooth voltage U_{ZN} in the region of the present interval d1 is of such magnitude that it is in the manipulation range MB. This results in a manipulation signal MS being initiated, with the initiation of the manipulation signal indicating a malfunction on the tachograph or prompting logging of the incorrect states in the tachograph. It is also possible to disable the tachograph, so that the operator of the vehicle has to visit a workshop in order to have the tachograph enabled again.

The method according to one embodiment of the invention and a sensor arrangement according to the invention can thus be used to recognize a manipulation attempt, possibly to initiate readjusting of the threshold values and to indicate a malfunction in the tachograph if the sensor signal is outside of an allocated operating range. As a result of a malfunction in the tachograph being initiated, the alleged fraudster needs to take the tachograph to the specialist dealer for maintenance, which takes up far more time than the time gained by the manipulation.

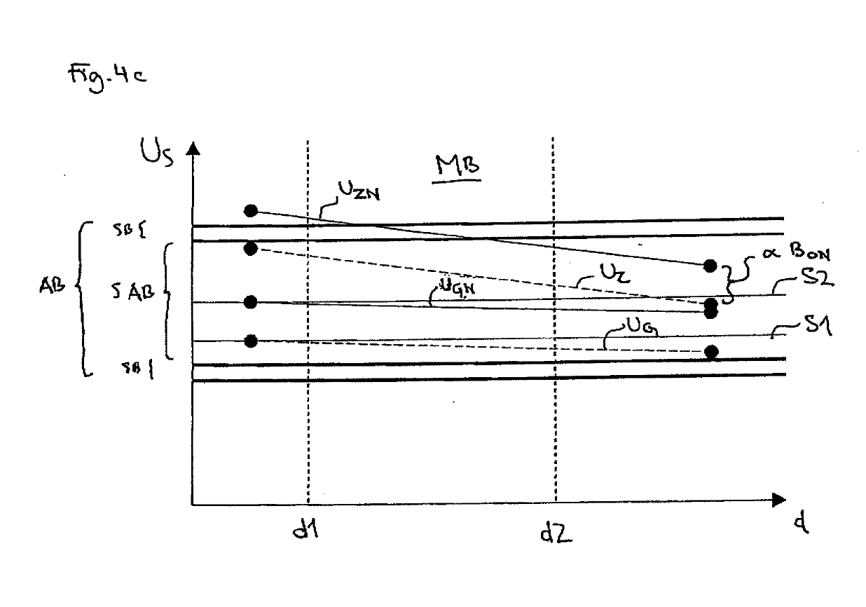

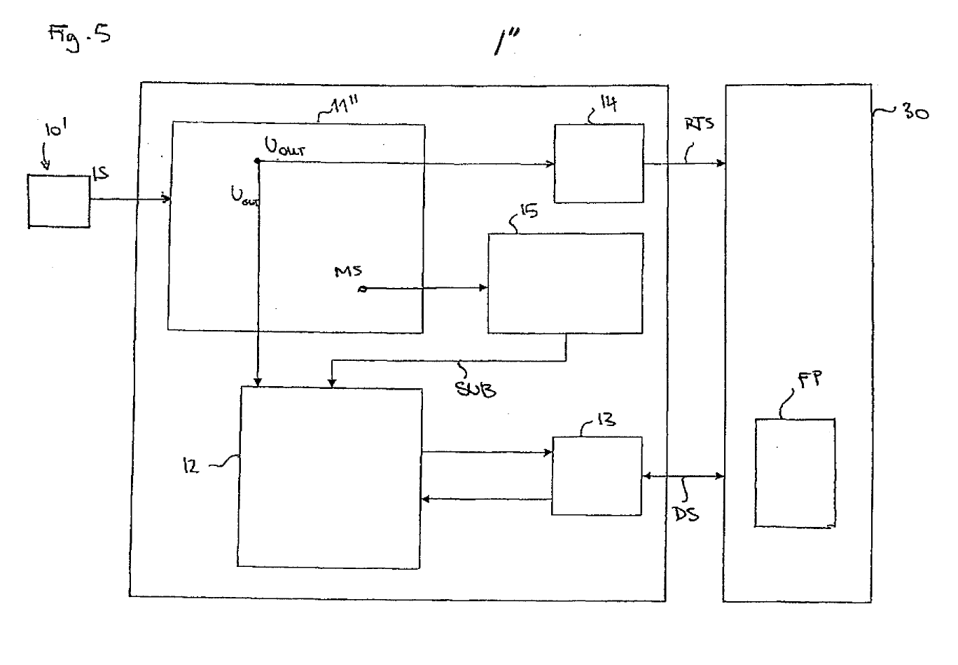

Finally, FIG. 5 is used to explain an exemplary embodiment of a tachograph arrangement. The sensor arrangement 1″ has a sensor 10′ which provides a digital sensor signal I_{S}. By way of example, the digital output signal may be pulse-width-modulated. The sensor signal I_{S} is supplied to an apparatus for signal processing 11″ which comprises a digital microcontroller. The latter simulates a first and a second comparator, wherein the first comparator compares the sensor signal I_{S} with a threshold value and generates a pulse generator signal Uₒᵤₜ therefrom.

A second comparator which is present in the microcontroller establishes whether the sensor signal I_{S} is operating within an admissible operating range. If this is not the case, a manipulation signal MS is output. When a manipulation signal MS is output, it is forwarded to the power supply unit 15. The power supply unit 15 then initiates a power outage which is forwarded as a signal SUB to the microcontroller 12. The microcontroller 12 is connected to the driver 13 for the tachograph 30, conditions the signal SUB and forwards it to the driver 13, which transmits the signal SUB as an encrypted data signal DS to the tachograph 30. The tachograph 30 records the encrypted data signal DS in the apparatus FP for error logging and triggers a malfunction in the tachograph.

The microcontroller 12 is also supplied with the pulse generator signal Uₒᵤₜ. This allows implementation of further variants of the evaluation mechanisms between the signal SUB and the pulse generator signal Uₒᵤₜ. In addition, the pulse generator signal Uₒᵤₜ is transmitted to the signal driver 14, which transmits the pulse generator signal as a realtime signal RTS to the tachograph 30 for the purpose of further processing.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-10. (canceled)

11. A sensor arrangement, comprising:
a sensor configured to produce a sensor signal based at least in part on a magnitude of a magnetic field; and
an apparatus for signal processing having
a first comparator configured to compare the sensor signal with at least one threshold value and produce a pulse generator signal having one of a first and second value based at least in part on the comparison; and
a second comparator configured to compare the sensor signal with a prescribed operating range and initiate a manipulation signal if a value of the sensor signal is outside of the prescribed operating range to recognize a manipulation attempt.

12. The sensor arrangement as claimed in claim 11, further comprising
a third comparator configured to compare the sensor signal with a safe operating range defined by a further range of values,
wherein the safe operating range is completely embedded in the operating range.

13. The sensor arrangement as claimed in claim 11,
wherein the first comparator is configured to compare the sensor signal with at least two threshold values, the two threshold values being a switching hysteresis function.

14. The sensor arrangement as claimed in claim 11, wherein the apparatus is configured to dynamically readjust the sensor signal.

15. The sensor arrangement as claimed in claim 11, wherein the sensor is a Hall sensor.

16. The sensor arrangement as claimed in claim 11, wherein the apparatus comprises a microcontroller configured such that at least one of the first and the second comparator is embodied by the microcontroller.

17. The sensor arrangement as claimed in claim 11, wherein at least one of the first comparator comprises a Schmitt trigger and the second comparator comprises a window discriminator.

18. A tachograph arrangement comprising:
a tachograph;
a sensor arrangement coupled to the tachograph comprising:
a sensor configured to produce a sensor signal based on a magnitude of a magnetic field; and
an apparatus for signal processing having
a first comparator configured to compare the sensor signal with at least one threshold value and produce a pulse generator signal having one of a first and second value based on the comparison; and
a second comparator configured to compare the sensor signal with a prescribed operating range and initiate a manipulation signal if a value of the sensor signal is outside of the operating range to recognize a manipulation attempt; and
an apparatus configured to produce at least one of a malfunction log and an error log such that the incoming manipulation signal triggers the production of the one of the malfunction and the error log.

19. A method for recognizing a manipulation attempt on a sensor arrangement in a vehicle, wherein the sensor arrangement comprises a sensor configured to produce a sensor signal on a proportional basis of the magnitude of a magnetic field and an apparatus for signal processing the sensor signal, the method comprising:
a) introducing a first and a second comparator for signal processing, wherein an input signal for the first and second comparators is the sensor signal;
b) defining at least one threshold value for the first comparator based on values of the sensor signal in a nominal operating state of the sensor;
c) defining an operating range for the second comparator based on values of the sensor signal in the nominal operating state of the sensor; and
c) comparing a value for the sensor signal in an actual operating state of the sensor arrangement with the operating range of the second comparator, and
d) initiating a manipulation signal if the value of the sensor signal in the actual operating state is outside of the operating range.

20. The method as claimed in claim 19, wherein the threshold value in the actual operating state is matched to values of the sensor signal in the actual operating state.

21. The sensor arrangement as claimed in claim 13,
wherein the switching hysteresis function is switching hysteresis function that can be readjusted based on a magnitude of the sensor signal.

22. The sensor arrangement as claimed in claim 15, wherein the Hall sensor has an amplifier.
